(19) United States
(12) Patent Application Publication
(10) Pub. No.: US 2003/0057421 A1
(43) Pub. Date: Mar. 27, 2003

(54) High flux light emitting diode having flip-chip type light emitting diode chip with a transparent substrate

(76) Inventor: Tzer-Perng Chen, Hsinchu City (TW)

Correspondence Address: SUPREME PATENT SERVICES, POST OFFICE BOX 2339, SARATOGA, CA, 95070, US

(21) Appl. No.: 09/964,719

(22) Filed: Sep. 27, 2001

(51) Int. Cl. H01L 27/15; H01L 31/12; H01L 33/00

(52) U.S. Cl. 257/79

(57) ABSTRACT

A high flux light emitting diode comprises a base substrate, a flip-chip type light emitting diode chip with a transparent substrate, and a cover substrate. The cover substrate has a center hole with a slanted reflective sidewall. The light emitting diode chip is disposed within the center hole. The base substrate is divided by a middle insulation region into two parts that connect the two electrodes of the light emitting diode chip. Highly thermally and electrically conductive material is used to form the base substrate for conducting a high current and dissipating heat efficiently. A transparent resin or epoxy is used to cover the enter hole and seal the diode chip. High intensity light can be emitted because the light is transmitted directly, reflected by a reflective electrode of the diode chip, or redirected by the reflective sidewall to exit the center hole of the cover substrate.

### FIELD OF THE INVENTION

The present invention generally relates to a light emitting diode, and more specifically to a high output light emitting diode having a flip-chip type light emitting diode chip.

### BACKGROUND OF THE INVENTION

Because a light emitting diode has the advantage of small size, long life and low power consumption, it has been widely used in the signal indicators of an audio equipment, the back light source of a cellular phone, the illuminating elements of a bulletin board, and the third brake light of an automobile. In recent years, new materials such as AlGaInP and AlGaInN are successfully used in manufacturing light emitting diodes that emit light with higher intensity. Therefore, it has become possible to replace conventional incandescent bulbs with light emitting diodes in many applications. Light emitting diodes can now be found in traffic signal lights, and tail lights or signal lights of a car. As the light intensity of a light emitting diode increases, it is very likely that light emitting diodes will replace lighting source such as fluorescence lights or energy saving light bulbs.

A light emitting diode usually operates with an electrical current of 20 mA at 2 to 3.5 volts. Consequently, each light emitting diode consumes about 40 to 70 mW of power. With the consumption of 40 to 70 mW, the most efficient light emitting diode currently available in the industry can only generate 1˜5 lumin of light intensity. For lighting purpose, it is generally necessary to have thousands of lumin of light intensity. Therefore, several hundreds of light emitting diodes are required to meet the requirement. It is not practical in terms of cost, size or volume.

One approach to overcoming the low luminance problem of a light emitting diode is increasing the operating current of the light emitting diode. For example, if the operating current could be increased to 100 mA, the luminance of the light emitting diode would be increased by a factor of 5. Consequently, the number of light emitting diodes required would be reduced by the same factor.

A conventional light emitting diode structure as shown in FIGS. 5(a) and 5(b) can not increase output light proportionally as the current increases when the light emitting diode is operated at a high current. In general, the base substrate of a conventional light emitting diode as shown in FIG. 5(b) is formed by a PC board or an alumina ceramic material that does not dissipate heat efficiently. Because of the poor heat dissipation in the conventional light emitting diode, a higher current significantly decreases the life time of a light emitting diode. As shown in FIG. 5(a), the lead frames are made of metal materials such as Kovar or Copper. However, the frame is too thin to dissipate the generated heat effectively.

### SUMMARY OF THE INVENTION

This invention has been made to increase the light output power of a conventional light emitting diode. The primary object of this invention is to provide a new structure for increasing the operating current of the light emitting diode. Accordingly, the light emitting diode comprises a flip-chip type light emitting diode chip with a transparent substrate for emitting light. A base substrate is divided by an insulation region into two parts that are connected to the positive and negative electrodes of the light emitting diode chip respectively. The base substrate which is highly conductive both electrically and thermally is used to conduct a high current as well as dissipate the heat generated from the light emitting diode chip efficiently.

Another object of the invention is to provide a structure of a light emitting diode that can reduce light being absorbed in the light emitting diode structure so as to increase the light output. In the present invention, a cover substrate that comprises a hole in the center area is provided. The flip-chip type light emitting diode chip is disposed in the center area. The cover substrate comprises a white and highly reflective material or the sidewall of the hole is coated with a white and highly reflective material. A transparent resin or epoxy fills the hole to form a convex lens that covers and seals the light emitting diode chip.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a cross sectional view of a preferred embodiment of the high flux light emitting diode having a flip-chip type light emitting diode chip according to this invention.

FIG. 2 is a cross sectional view of the flip-chip type light emitting diode chip having an InGaN active layer.

FIG. 3 illustrates how the light emitted from the active layer is transmitted, reflected or directed through the hole of the cover substrate of the light emitting diode.

FIG. 4 is a cross sectional view of the flip-chip type light emitting diode chip having an AlGaInP active layer.

FIGS. 5(a) and (b) show a conventional light emitting diode and the cross sectional view of its light emitting diode chip.

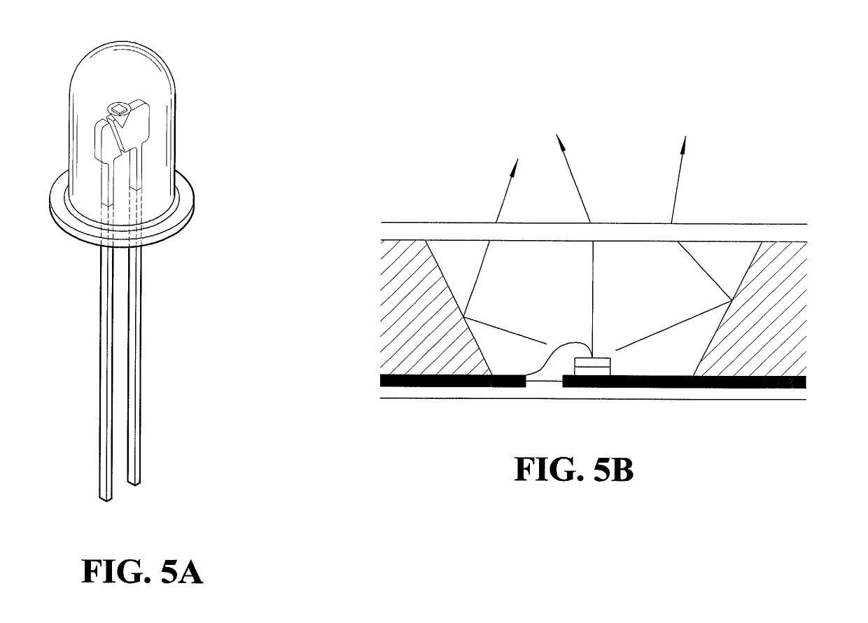

### DETAILED DESCRIPTION OF THE PREFERRED EMBODIMENTS

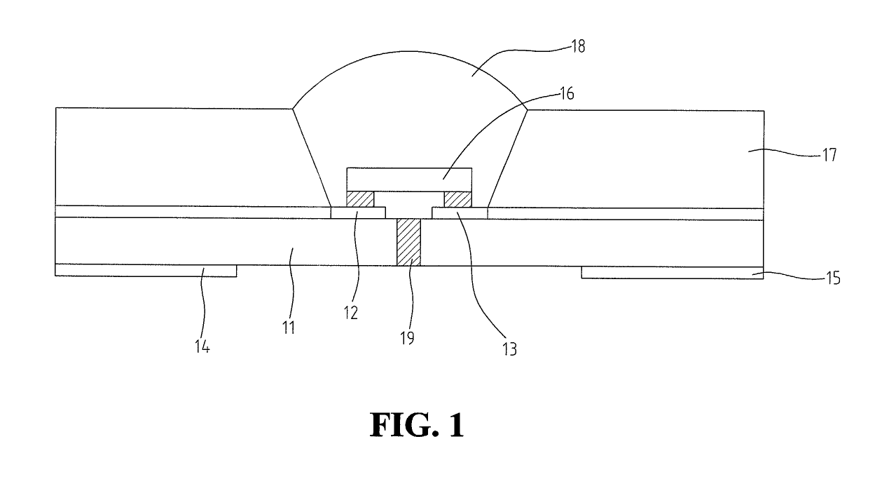

FIG. 1 shows the cross-sectional view of a preferred embodiment of the light emitting diode according to the present invention. The light emitting diode comprises a base substrate 11, a flip-chip type light emitting diode chip 16, a cover substrate 17 and a convex lens 18 formed by a transparent resin or epoxy. The base substrate 11 has an insulating region 19 which separates the base substrate 11 into two non-connected electrical conductive parts.

Below and above the base substrate 11 are several metal layers 12, 13, 14, and 15. The metal layers 12, 13 are connected to the p and n electrodes of the light emitting diode chip 16. The metal layers 14, 15 are connected to an external circuit. In addition to fixing the light emitting diode chip 16, the base substrate 11 also needs to conduct electrical current and effectively dissipate the heat generated by the light emitting diode chip 16. Therefore, it is important that the material of the base substrate 11 is highly conductive both electrically and thermally.

Copper (Cu) has a thermal conductivity of 398 W(m° K) and very high electrical conductivity. It is one of the best materials for the base substrate 11. Aluminum (Al) has a thermal conductivity of 240 W(m° K) and is also a good candidate for the base substrate 11. Silicon (Si) has a thermal conductivity which is about ⅓ of the thermal conductivity of copper. However, it is also an appropriate material for the base substrate 11 because it is easy to process.

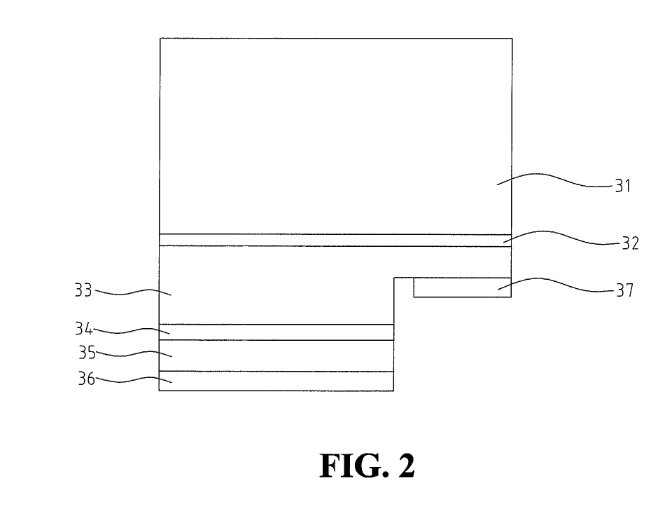

FIG. 2 shows the structure of the flip-chip type light emitting diode chip that has a transparent substrate. The light emitting diode chip illustrated in FIG. 2 is an InGaN light emitting diode that emits blue light. The light emitting diode chip comprises a sapphire substrate 31, a GaN buffer layer 32, an n-type GaN layer 33, an InGaN active layer 34 and a p-type GaN layer 35. The InGaN active layer 34 is the light emitting layer. In this embodiment, the active layer may comprise AlGaInN instead of InGaN.

Below the p-type GaN layer 35 is a p-type electrode 36. An n-type electrode 37 is also formed in contact with the n-type GaN layer 33. The n-type electrode 37 has a smaller area which only contacts part of the n-type GaN layer 33. The p-type electrode has a larger area which is in contact with most of the p-type GaN layer 35. It also has a high reflectivity to reflect the light emitted from the active layer. These n-type and p-type electrodes can be bonded to the metal layers 12, 13 of the base substrate 11 by means of bonding agent such as gold or an alloy comprising gold and tin.

Preferably the cover substrate 17 may be formed by a white and high reflectivity material. The center of the cover substrate 17 has a hole which is large enough for disposing the flip-chip type light emitting diode chip 16. The sidewall of the hole is designed with a slanted shape so as to reflect the side light emitted from the light emitting diode chip. It is also possible to use an absorptive material for the cover substrate 17 if the sidewall of the hole is coated with a white and high reflectivity reflector in order to reflect the side light. The cover substrate 17 is bonded to the base substrate 11 by the adhesive layer as illustrated in FIG. 1. The opening of the hole is filled with a transparent resin or epoxy 18 to cover and seal the light emitting diode chip. The transparent epoxy also forms a convex lens to focus the light emitted from the light emitting diode chip so that the emitted light becomes directional.

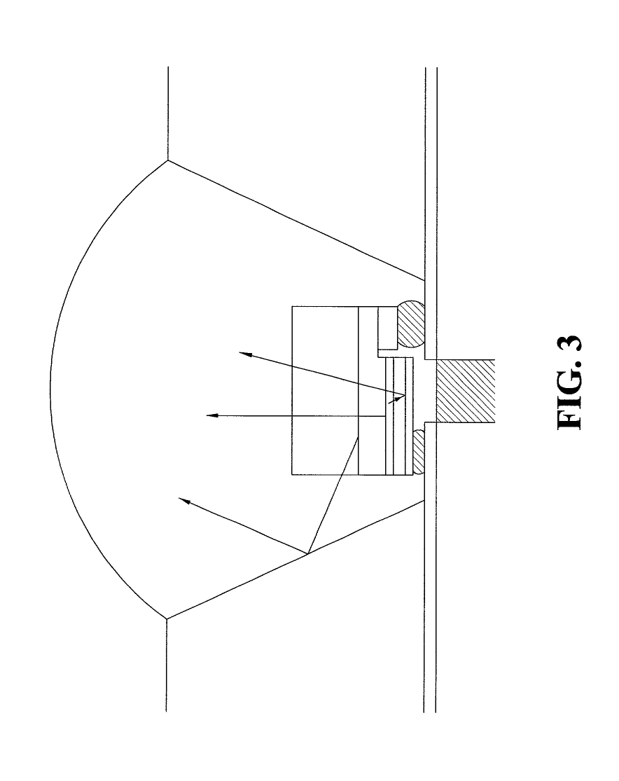

According to the present invention, a transparent substrate is used for the flip-chip type light emitting diode chip. The light emitted from the light emitting diode can be transmitted through the substrate directly, reflected from the p-type electrode and then transmitted through the substrate, or reflected from the p-type electrode towards the reflected sidewall of the hole and then transmitted through the hole as illustrated in FIG. 3. As a result, the light emitting diode greatly reduces light absorption and its light emission efficiency is significantly increased.

Because the base substrate used for the light emitting diode has high thermal conductivity, heat generated by the light emitting diode chip can be dissipated effectively to increase its life time. In the present invention, the distance between the active light emitting layer and the base substrate is very short. The heat generated by a high current in the light emitting layer can be transferred to the base substrate very efficiently. Therefore, the light emitting diode can operate at a high current.

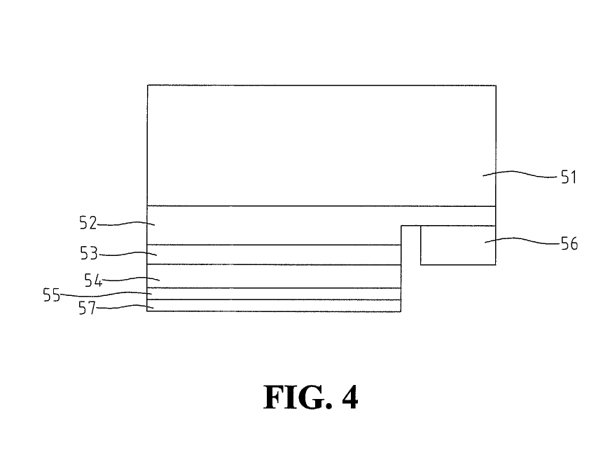

FIG. 4 shows the structure of another flip-chip type light emitting diode chip that has a transparent substrate. The light emitting diode illustrated in FIG. 4 is an AlGaInP light emitting diode. The light emitting diode chip comprises a sapphire substrate 51, a p-type AlGaInP lower confining layer 52, an AlGaInP active layer 53, an n-type AlGaInP upper confining layer 54 and an n-type InGaP or AlGaP ohmic contact layer 55. The AlGaInP active layer 53 is the light emitting layer.

Below the n-type InGaP ohmic contact layer 55 is an n-type electrode 57. The n-type electrode 57 also serves as a reflector. A p-type electrode 56 is also formed in contact with the p-type AlGaInP lower confining layer 52. The p-type electrode 56 has a smaller area which only contacts part of the p-type AlGaInP lower confining layer 52. The n-type electrode 57 has a larger area which is in contact with most of the n-type InGaP ohmic contact layer 55. These n-type and p-type electrodes can be bonded to the metal layers 12, 13 of the base substrate 11 by means of bonding agents.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A light emitting diode comprising:
an electrically and thermally conductive base substrate, said base substrate being divided into two electrically isolated parts by a middle insulating region;
a cover substrate adhered to said base substrate, said cover substrate having a hole in a center region, said hole having a slanted reflective sidewall;
a flip-chip type light emitting diode chip disposed within said hole and bonded to said base substrate, said flip-chip type light emitting diode chip having a transparent substrate; and
a transparent material filling said hole and sealing said flip-chip light emitting diode chip.

2. The light emitting diode according to claim 1, wherein said cover substrate is formed by a white and high reflectivity material.

3. The light emitting diode according to claim 1, wherein said slanted reflective sidewall is coated with a white and high reflectivity material.

4. The light emitting diode according to claim 1, wherein said transparent material filling said hole forms a convex lens.

5. The light emitting diode according to claim 1, wherein said base substrate is silicon.

6. The light emitting diode according to claim 1, wherein said base substrate is copper.

7. The light emitting diode according to claim 1, wherein said base substrate is aluminum.

8. The light emitting diode according to claim 1, wherein said flip-chip type light emitting diode chip is an AlGaInP light emitting diode chip.

9. The light emitting diode according to claim 1, wherein said flip-chip type light emitting diode chip is an AlGaInN light emitting diode chip.

10. The light emitting diode according to claim 1, wherein said flip-chip type light emitting diode chip is an InGaN light emitting diode chip.
